(19) United States
(12) Patent Application Publication
(10) Pub. No.: US 2015/0173185 A1
(43) Pub. Date: Jun. 18, 2015

(54) CIRCUIT BOARD AND CIRCUIT BOARD MANUFACTURING METHOD

(71) Applicant: Murata Manufacturing Co., Ltd., Kyoto (JP)

(72) Inventors: Satoshi Ito, Kyoto (JP); Yoichi Moriya, Kyoto (JP); Tetsuo Kanamori, Kyoto (JP); Yukihiro Yagi, Kyoto (JP); Yuki Yamamoto, Kyoto (JP)

(21) Appl. No.: 14/635,429

(22) Filed: Mar. 2, 2015

Related U.S. Application Data
(63) Continuation of application No. PCT/JP2013/070841, filed on Aug. 1, 2013.

(30) Foreign Application Priority Data
Sep. 20, 2012 (JP) 2012-206470

(51) Int. Cl. H05K 1/02; H05K 3/46; H05K 3/06; H05K 1/11

(52) U.S. Cl. CPC H05K 1/0298; H05K 1/115; H05K 3/4661; H05K 3/06

(57) ABSTRACT

A circuit board structure and a manufacturing method for a circuit board that ensures an electrical connection between a metal foil and a projection without using a conductive adhesive and is less likely to cause a decrease in the reliability of the connection due to the interlayer separation or the like is provided. A circuit board includes an insulating layer, a lower main surface wiring pattern and an upper main surface wiring pattern disposed on either side of the insulating layer, and an interlayer connection conductor passing through the insulating layer in a thickness direction and electrically connecting to the lower main surface wiring pattern and the upper main surface wiring pattern. The interlayer connection conductor is formed integrally with the lower main surface wiring pattern, and is bonded to the upper main surface wiring pattern via an intermetallic compound.

### BACKGROUND OF THE INVENTION

1. Field of the Invention

The present invention relates to structures of and manufacturing methods for circuit boards that have wiring patterns.

2. Description of the Related Art

In circuit boards, interlayer connection conductors (via hole conductors) are provided in order to electrically connect wiring patterns in different layers. An interlayer connection conductor is generally formed by providing a through-hole in the circuit board and then plating an inner wall of the through-hole. This formation method is problematic in terms of productivity and economics, in that the chemical agents used in the plating process are expensive and the process takes a long time.

Accordingly, as a method for manufacturing a circuit board that does not require a plating process, there is a method of forming circular cone-shaped projections on one surface of a metal plate, forming an insulating layer having a thickness approximately equal to the height of the projections on the projection side of the metal plate, bonding a metal foil to a surface of the insulating layer, and patterning the metal foil and the metal plate to form the circuit board (see Patent Document 1, for example).
Patent Document 1: Japanese Unexamined Patent Application Publication No. 2000-68641

### BRIEF SUMMARY OF THE INVENTION

In the case where the circuit board is manufactured using a projection provided on a metal plate as the interlayer connection conductor, an electrical connection between a metal foil and the projection has been ensured by applying a conductive adhesive to a leading end portion (upper surface) of the projection. However, when affixing the metal foil, there is a risk that the conductive adhesive will spread in a planar direction, and as a result there have been cases where unwanted electrification occurs in the circuit board and causes shorting.

In addition, thermal stress is generated by a difference in expansion coefficients between an insulating layer and the metal foil arising due to the expansion and the contraction in the circuit board caused by the temperature changes, resulting in a risk that the metal foil will separate from the insulating layer; this in turn has caused the electrical connection provided by the conductive adhesive to break down and cause electrification problems.

Accordingly, it is an object of the present invention to provide a circuit board structure and a manufacturing method for a circuit board that ensure an electrical connection between a metal foil and a projection without using a conductive adhesive and is less likely to cause a decrease in the reliability of the connection due to the interlayer separation or the like.

A circuit board according to the present invention includes an insulating layer, a first wiring pattern and a second wiring pattern disposed on either side of the insulating layer in a thickness direction, and an interlayer connection conductor passing through the insulating layer in the thickness direction and electrically connecting to the first wiring pattern and the second wiring pattern; here, the interlayer connection conductor is formed integrally with the first wiring pattern and bonded to the second wiring pattern via an intermetallic compound.

According to this configuration, the first wiring pattern and the interlayer connection conductor are formed integrally as the same single metal member, and thus there is no junction boundary between the first wiring pattern and the interlayer connection conductor, resulting in a strong mechanical connection and a strong electrical connection between the first wiring pattern and the interlayer connection conductor. In addition, because the second wiring pattern and the interlayer connection conductor are chemically bonded via the intermetallic compound, there is a more stable bond than that achieved by physical contact, affixing using a conductive adhesive, or the like, and thus there is a strong mechanical connection and electrical connection between the second wiring pattern and the interlayer connection conductor. Accordingly, the connection between the first wiring pattern and the second wiring pattern becomes highly reliable. Furthermore, the circuit board can be formed without using a conductive adhesive, which makes it possible to prevent the occurrence of shorting due to the conductive adhesive spreading out.

In the aforementioned circuit board, it is preferable that the interlayer connection conductor be bonded to the second wiring pattern in a state in which the interlayer connection conductor extends further toward the second wiring pattern beyond a junction boundary between the second wiring pattern and the insulating layer.

According to this configuration, a junction boundary between the interlayer connection conductor and the second wiring pattern is located on a different plane than a junction boundary between the insulating layer and the second wiring pattern. As such, since the thermal stress generated due to the temperature changes in the circuit board is less likely to act on the junction boundary between the interlayer connection conductor and the second wiring pattern, the separation of the junction boundary between the interlayer connection conductor and the second wiring pattern is less likely to occur, which further increases the reliability of the connection.

In the aforementioned circuit board, it is preferable that a junction boundary between the interlayer connection conductor and the second wiring pattern be roughened.

According to this configuration, a surface area of the bond between the interlayer connection conductor and the second wiring pattern is increased, resulting in a stronger connection between the interlayer connection conductor and the second wiring pattern. Accordingly, the connection is even further reliable.

A method for manufacturing a circuit board according to this invention manufactures the aforementioned circuit board, and it is preferable for the method to include a pre-reaction medium formation process, an interlayer connection conductor forming process, a layering process, a wiring pattern forming process, and a heating process. In the pre-reaction medium formation process, a pre-reaction medium of the intermetallic compound is formed on one surface of a metal plate. In the interlayer connection conductor forming process, a multilayer body of the pre-reaction medium and the metal plate is partially removed from a side on which the pre-reaction medium is located except that a region for the interlayer connection conductor is not removed. In the layering process, the insulating layer and a metal foil are formed, in which the interlayer connection conductor is embedded in the insulating layer and the metal foil is bonded to a surface of the insulating layer are formed on the multilayer body. In the wiring pattern forming process, the first wiring pattern is formed from the metal plate and the second wiring pattern is formed from the metal foil. In the heating process, the intermetallic compound is formed by heating the multilayer body to react the pre-reaction medium.

In the aforementioned method for manufacturing a circuit board, it is preferable that the insulating layer formed in the layering process is thinner than a height of the interlayer connection conductor, and the metal foil pressure-bonded to the insulating layer in the layering process is thicker than a height at which the interlayer connection conductor projects from the insulating layer.

According to the present invention, the first wiring pattern and the interlayer connection conductor are formed integrally, and the second wiring pattern and the interlayer connection conductor are chemically bonded via the intermetallic compound; accordingly, there is a strong mechanical connection and a strong electrical connection between the first wiring pattern, the second wiring pattern, or the like and the interlayer connection conductor. Accordingly, the interlayer separation is less likely to occur between the first wiring pattern, the second wiring pattern, or the like and the insulating layer, and thus the connection is highly reliable.

In addition, the second wiring pattern and the interlayer connection conductor are bonded by chemically reacting the pre-reaction medium of the intermetallic compound, making it unnecessary to apply a conductive adhesive on the interlayer connection conductor during manufacture; this makes it possible to prevent the occurrence of shorting caused by the conductive adhesive spreading.

### BRIEF DESCRIPTION OF THE SEVERAL VIEWS OF THE DRAWINGS

FIG. 1 is a schematic cross-sectional view of a circuit board according to a first embodiment.

FIGS. 2A to 2E are schematic diagrams illustrating a process for manufacturing a circuit board according to the first embodiment.

FIG. 3 is a graph illustrating the results of carrying out a thermal shock test on the circuit board according to the first embodiment.

FIG. 4 is a schematic cross-sectional view of a circuit board according to a second embodiment.

FIGS. 5A to 5E are schematic diagrams illustrating a process for manufacturing a circuit board according to the second embodiment.

FIG. 6 is a graph illustrating the results of carrying out a thermal shock test on the circuit board according to the second embodiment.

FIG. 7 is a schematic cross-sectional view of a circuit board according to a third embodiment.

### DETAILED DESCRIPTION OF THE INVENTION

### First Embodiment

A circuit board according to a first embodiment of the present invention will be described hereinafter.

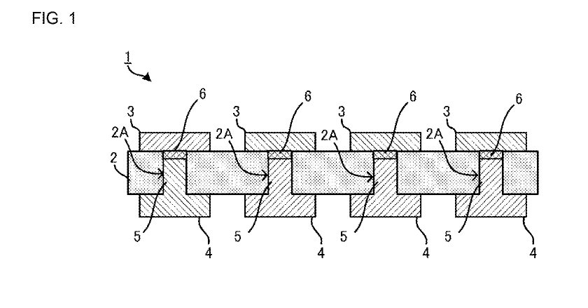

FIG. 1 is a schematic cross-sectional view of a circuit board 1 according to the first embodiment of the present invention. The circuit board 1 includes an insulating layer 2 comprising an insulating resin, an upper main surface wiring pattern 3 comprising a conductive material, a lower main surface wiring pattern 4 comprising a conductive material, and interlayer connection conductors 5 comprising a conductive material.

The insulating layer 2 has a flat plate shape having an upper main surface and a lower main surface. Cylindrical through-holes 2A that open in the upper main surface and the lower main surface are formed in the insulating layer 2.

Here, the upper main surface wiring pattern 3 is lands, a wiring pattern, or the like on which is mounted an electrical component (not illustrated). The upper main surface wiring pattern 3 is formed as a pattern on the upper main surface of the insulating layer 2 so as to cover the through-holes 2A.

Here, the lower main surface wiring pattern 4 is connected to electrodes on a main board (for example, a motherboard) (not illustrated), used as a wiring pattern within the board, or the like. The lower main surface wiring pattern 4 is formed as a pattern on the lower main surface of the insulating layer 2 so as to cover the through-holes 2A.

The interlayer connection conductors 5 are inserted into the through-holes 2A and pass through the insulating layer 2. The interlayer connection conductors 5 are electrically connected to the upper main surface wiring pattern 3 at upper end portions and are electrically connected to the lower main surface wiring pattern 4 at lower end portions. Accordingly, the electrical component and the main board are electrically connected to each other via the upper main surface wiring pattern 3, the interlayer connection conductors 5, and the lower main surface wiring pattern 4.

The interlayer connection conductors 5 and the lower main surface wiring pattern 4 are formed as a single integrated entity. In other words, the lower main surface wiring pattern 4 is a first wiring pattern formed integrally with the interlayer connection conductors 5, and the interlayer connection conductors 5 and the lower main surface wiring pattern 4 comprise the same metal member without a junction boundary present therebetween. On the other hand, the interlayer connection conductors 5 and the upper main surface wiring pattern 3 are formed as separate entities. In other words, the upper main surface wiring pattern 3 is a second wiring pattern, and the interlayer connection conductors 5 and the upper main surface wiring pattern 3 comprise metal members that are not formed integrally. An intermetallic compound 6 is formed at a junction boundary between the interlayer connection conductors 5 and the upper main surface wiring pattern 3. The intermetallic compound 6 is chemically bonded to the upper main surface wiring pattern 3 and is chemically bonded to the interlayer connection conductors 5.

In this manner, the lower main surface wiring pattern 4 and the interlayer connection conductors 5 are formed integrally, and thus there is a strong mechanical connection and electrical connection between the lower main surface wiring pattern 4 and the interlayer connection conductors 5. In addition, because the upper main surface wiring pattern 3 and the interlayer connection conductors 5 are chemically bonded via the intermetallic compound 6, there is a more stable bond than that achieved by physical contact, affixing using a conductive adhesive, or the like, and thus there is a strong mechanical connection and electrical connection between the upper main surface wiring pattern 3 and the interlayer connection conductors 5. Accordingly, the connection between the upper main surface wiring pattern 3 and the lower main surface wiring pattern 4 is highly reliable.

Next, a method for manufacturing the circuit board 1 according to the first embodiment will be described.

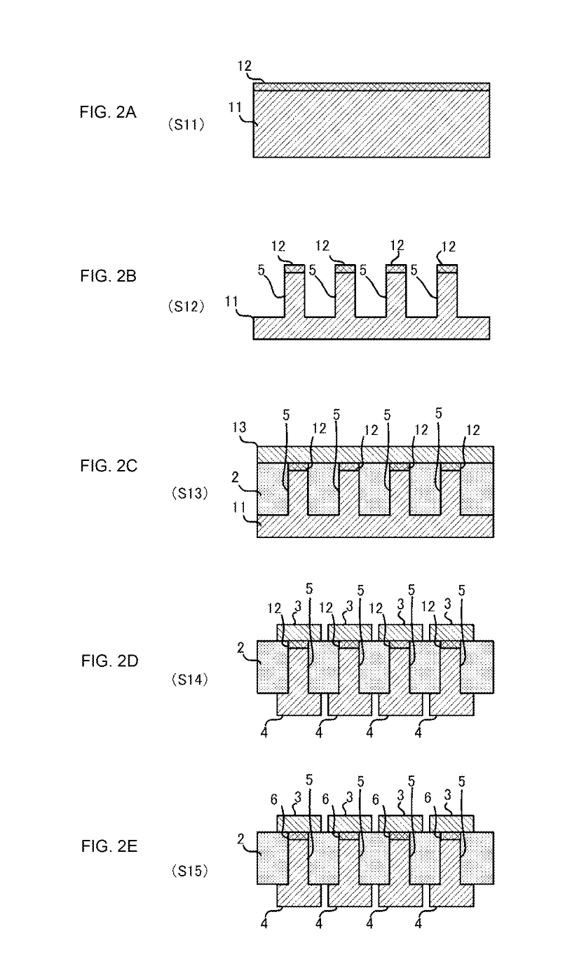

FIGS. 2A to 2E are schematic diagrams illustrating a process for manufacturing the circuit board 1 according to the first embodiment.

In the process for manufacturing the circuit board 1, first, a pre-reaction medium formation process is carried out. In the pre-reaction medium formation process, as indicated in FIG. 2A (S11), a flat plate-shaped metal plate 11 is prepared, and a pre-reaction medium 12 comprising an intermetallic compound is formed on one surface of the metal plate 11. It is preferable for the pre-reaction medium 12 to be formed as a layer upon the metal plate 11 through a plating technique. Any material may be used for the pre-reaction medium 12 as long as it is a material capable of forming an intermetallic compound with the material of the metal plate 11. For example, in the case where copper is used for the metal plate 11, it is favorable to combine it with tin or the like, which forms an alloy with copper through low-temperature heating, as the pre-reaction medium 12. Note that the pre-reaction medium 12 may be layered upon the metal plate 11 by bonding a plate-form pre-reaction medium 12 to the metal plate 11, applying a liquid-form pre-reaction medium 12 to the metal plate 11, melting or vaporizing the metal and depositing the metal on the metal plate 11, or the like.

Next, an interlayer connection conductor forming process is carried out. In the interlayer connection conductor forming process, as illustrated in FIG. 2B (S12), a multilayer body comprising the metal plate 11 and the pre-reaction medium 12 is partially removed from the side on which the pre-reaction medium 12 is located, and the interlayer connection conductors 5 are formed. It is favorable for the interlayer connection conductors 5 to be formed through an etching technique. In this case, it is preferable to laminate a dry film resist to both main surfaces of the multilayer body comprising the metal plate 11 and the pre-reaction medium 12, expose and develop the resist, and then carry out the etching. Note that the interlayer connection conductors 5 may be formed using a mechanical process such as a cutting technique.

Next, a layering process is carried out. In the layering process, as illustrated in FIG. 2C (S13), the insulating layer 2 is layered upon the side of the multilayer body comprising the metal plate 11 and the pre-reaction medium 12 on which the interlayer connection conductors 5 are located, and a metal foil 13 is bonded to the surface side of the insulating layer 2. The insulating layer 2 has almost the same thickness as the length of the interlayer connection conductors 5, and thus the interlayer connection conductors 5 are embedded within the insulating layer 2. For example, it is preferable for the insulating layer 2 and the metal foil 13 to be pressure-bonded to the multilayer body by stacking an insulating resin sheet in a semicured state and a metal foil on the multilayer body and then compressing those elements.

Next, a wiring pattern forming process is carried out. In the wiring pattern forming process, as illustrated in FIG. 2D (S14), the lower main surface wiring pattern 4 is formed from the metal plate 11 exposed on the bottom surface of the multilayer body comprising the metal plate 11, the pre-reaction medium 12, the insulating layer 2, and the metal foil 13, and the upper main surface wiring pattern 3 is formed from the metal foil 13 exposed on the upper surface of the multilayer body. It is favorable for the lower main surface wiring pattern 4 and the upper main surface wiring pattern 3 to be formed through an etching technique. In this case, it is preferable to laminate a dry film resist to both main surfaces of the multilayer body comprising the metal plate 11 and the pre-reaction medium 12, form a negative pattern by exposing and developing the resist, and then carry out the etching.

Next, a heating process is carried out. In the heating process, as illustrated in FIG. 2E (S15), the multilayer body comprising the lower main surface wiring pattern 4, the interlayer connection conductors 5, the insulating layer 2, and the upper main surface wiring pattern 3 is heated, the multilayer body comprising the interlayer connection conductors 5, the insulating layer 2, and the upper main surface wiring pattern 3 is heated, the pre-reaction medium 12 provided on the upper end portions of the interlayer connection conductors 5 is reacted, and the intermetallic compound 6 is formed.

According to the method for manufacturing the circuit board 1 as described above, the interlayer connection conductors 5 and the upper main surface wiring pattern 3 are bonded through a chemical reaction of the pre-reaction medium 12 plated on the upper end portions of the interlayer connection conductors 5, and thus a conductive adhesive is not necessary to bond the interlayer connection conductors 5 to the upper main surface wiring pattern 3. Through this, the occurrence of shorting due to the conductive adhesive spreading out can be prevented.

Here, the results of carrying out a thermal shock test (heat cycle test) on a sample of the circuit board 1 and measuring a rate of change in resistance will be described.

As the sample of the circuit board 1, a multilayer body was formed by using a 0.5 mm-thick copper plate as the metal plate 11 and a 1 μm-thick tin film through plating as the pre-reaction medium in the pre-reaction medium formation process. In addition, in the interlayer connection conductor forming process, a resist having a pattern of circles 0.6 mm in diameter was provided on the multilayer body and 0.3 mm-high interlayer connection conductors 5 were formed through etching. Furthermore, in the layering process, through-holes 0.6 mm in diameter were opened in a semicured resin sheet in locations overlapping with the interlayer connection conductors 5 using a punching machine such as a mechanical punch, and the resin sheet was then stacked on the metal plate 11 so as to have a thickness of 0.3 mm. Then, a 0.2 mm-thick metal foil 13 was stacked on the surface of the resin sheet, the resin sheet and the metal foil 13 were thermally compressed using a thermal compression press, and the resin sheet was heated and cured in an oven, forming the insulating layer 2. Finally, the upper main surface wiring pattern 3 and the lower main surface wiring pattern 4 were formed in pattern by etching the metal foil 13 and the metal plate 11, the multilayer body was once again heated under heating conditions necessary to form the intermetallic compound 6 from the pre-reaction medium, and the manufacture of the circuit board 1 was completed.

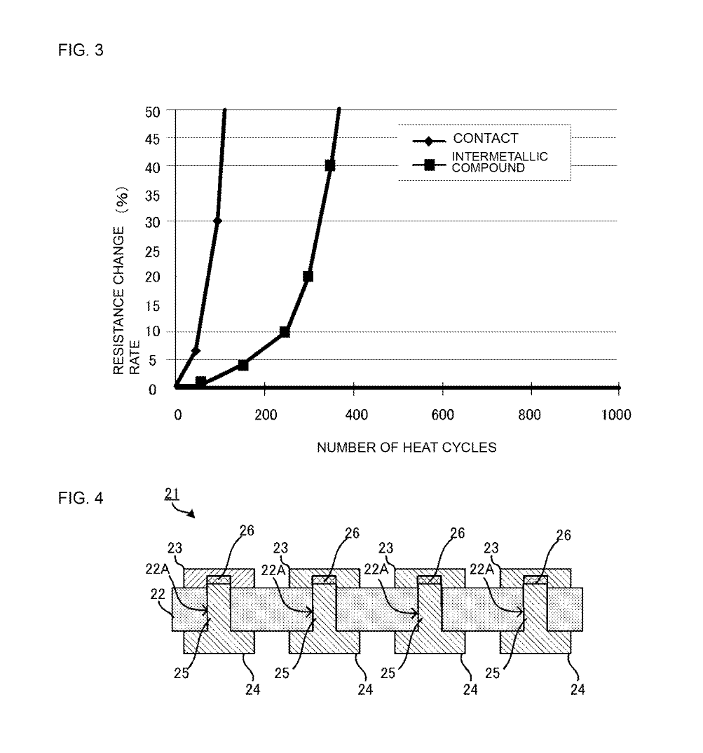

FIG. 3 is a diagram illustrating a relationship between a number of heat cycles and a resistance change rate for the sample of the circuit board 1. Note that the relationship between the number of heat cycles and the resistance change rate is illustrated here for the circuit board according to the embodiment as well as a circuit board according to a comparative example. A circuit board in which an intermetallic compound, a conductive adhesive, or the like is not used to bond the interlayer connection conductors and the upper main surface wiring pattern is used as the circuit board according to the comparative example.

With the circuit board according to the embodiment, the resistance change rate increases gradually up until approximately 200 heat cycles, and the resistance change rate then changes drastically when the number of heat cycles exceeds approximately 300. On the other hand, with the circuit board according to the comparative example, the resistance change rate increases drastically from a stage where the number of heat cycles is less than 100. Based on this, it can be seen that in the circuit board according to the embodiment, the bond between the interlayer connection conductors 5 and the upper main surface wiring pattern 3 is more stable than in the circuit board according to the comparative example. In other words, it was successfully confirmed that a highly-reliable connection can be achieved by chemically bonding the interlayer connection conductors 5 to the upper main surface wiring pattern 3 using the intermetallic compound.

### Second Embodiment

Next, a circuit board according to a second embodiment of the present invention will be described.

FIG. 4 is a schematic cross-sectional view of a circuit board 21 according to the second embodiment of the present invention. The circuit board 21 includes an insulating layer 22 comprising an insulating resin, an upper main surface wiring pattern 23 comprising a conductive material, a lower main surface wiring pattern 24 comprising a conductive material, and interlayer connection conductors 25 comprising a conductive material. Although having approximately the same configuration as the aforementioned circuit board 1, the circuit board 21 differs from the aforementioned circuit board 1 in that the interlayer connection conductors 25 extend beyond the junction boundary between the upper main surface wiring pattern 23 and the insulating layer 22 toward the upper main surface wiring pattern 23, and an intermetallic compound 26 provided on upper end portions of the interlayer connection conductors 25 is embedded in the upper main surface wiring pattern 23.

In other words, the junction boundary between the interlayer connection conductors 25 and the upper main surface wiring pattern 23 is located on a different plane than the junction boundary between the insulating layer 22 and the upper main surface wiring pattern 23. Accordingly, since the thermal stress generated due to the temperature changes in the circuit board 21 is less likely to act on the junction boundary between the interlayer connection conductors 25 and the upper main surface wiring pattern 23, the separation of the junction boundary between the interlayer connection conductors 25 and the upper main surface wiring pattern 23 is less likely to occur, which further increases the reliability of the connection.

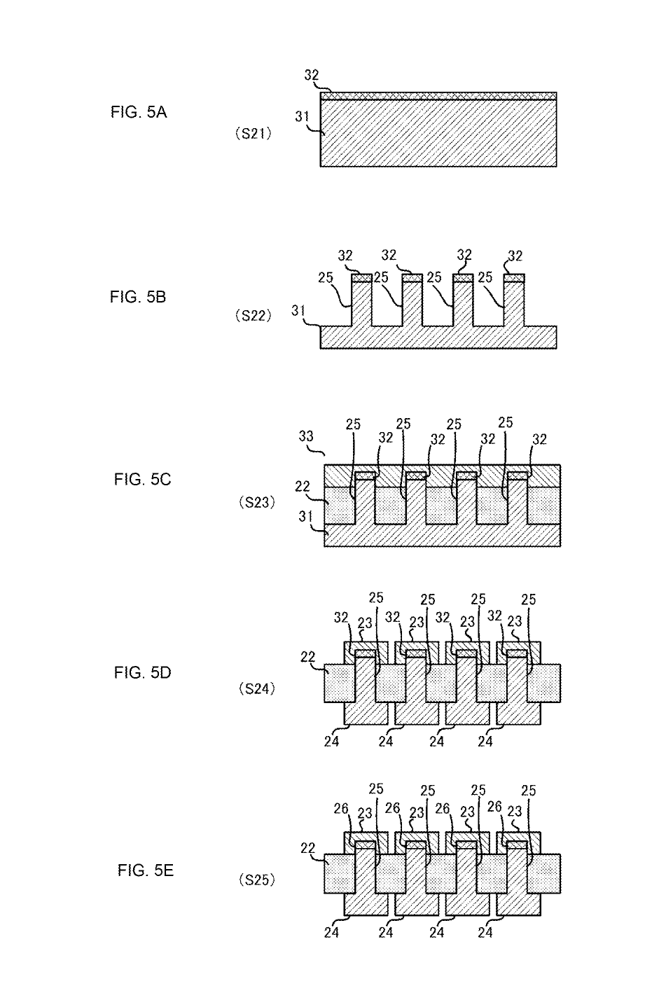

FIGS. 5A to 5E are schematic diagrams illustrating a process for manufacturing the circuit board 21 according to the second embodiment.

In the process for manufacturing the circuit board 21, first, the pre-reaction medium formation process is carried out. In the pre-reaction medium formation process, as indicated in FIG. 5A (S21), a flat plate-shaped metal plate 31 is prepared, and a pre-reaction medium 32 comprising an intermetallic compound is formed on one surface of the metal plate 31.

Next, the interlayer connection conductor forming process is carried out. In the interlayer connection conductor forming process, as illustrated in FIG. 5B (S22), a multilayer body comprising the metal plate 31 and the pre-reaction medium 32 is partially removed from the side on which the pre-reaction medium 32 is located, and the interlayer connection conductors 25 are formed.

Next, the layering process is carried out. In the layering process, as illustrated in FIG. 5C (S23), the insulating layer 22 is layered upon the side of the multilayer body comprising the metal plate 31 and the pre-reaction medium 32 on which the interlayer connection conductors 25 are located, and a metal foil 33 is bonded to the surface side of the insulating layer 22. The insulating layer 22 is thinner than the interlayer connection conductors 25, and as a result, the interlayer connection conductors 25 are caused to project from the insulating layer 22 and are embedded in the metal foil 33.

Next, the wiring pattern forming process is carried out. In the wiring pattern forming process, as illustrated in FIG. 5D (S24), the lower main surface wiring pattern 24 is formed from the metal plate 31 exposed on the bottom surface of the multilayer body comprising the metal plate 31, the pre-reaction medium 32, the insulating layer 22, and the metal foil 33, and the upper main surface wiring pattern 23 is formed from the metal foil 33 exposed on the upper surface of the multilayer body.

Next, the heating process is carried out. In the heating process, as illustrated in FIG. 5E (S25), the multilayer body comprising the lower main surface wiring pattern 24, the interlayer connection conductors 25, the insulating layer 22, and the upper main surface wiring pattern 23 is heated, the pre-reaction medium 32 provided on the upper end portions of the interlayer connection conductors 25 is reacted, and the intermetallic compound 26 is formed.

According to the method for manufacturing the circuit board 21 as described above, the interlayer connection conductors 25 and the upper main surface wiring pattern 23 are bonded through a chemical reaction of the pre-reaction medium 32 plated on the upper end portions of the interlayer connection conductors 25, and thus a conductive adhesive is not necessary to bond the interlayer connection conductors 25 to the upper main surface wiring pattern 23. Through this, the occurrence of shorting due to the conductive adhesive spreading out can be prevented.

Here, the results of carrying out a heat cycle test on a sample of the circuit board 21 and measuring a resistance change rate will be described.

As the sample of the circuit board 21, a multilayer body was formed by using a 0.5 mm-thick copper plate as the metal plate 31 and a 1 μm-thick tin film for plating as the pre-reaction medium 32 in the pre-reaction medium formation process. In addition, in the interlayer connection conductor forming process, a resist having a pattern of circles 0.6 mm in diameter was provided on the multilayer body and 0.3 mm-high interlayer connection conductors 25 were formed through etching. Furthermore, in the layering process, through-holes 0.6 mm in diameter were opened in a semicured resin sheet in locations overlapping with the interlayer connection conductors 25 using a punching machine such as a mechanical punch, the resin sheet was then stacked on the metal plate 31 so as to have a thickness of 0.25 mm, after which the interlayer connection conductors 25 was caused to project by approximately 0.05 mm from the surface of the metal plate 31. Then, a 0.2 mm-thick metal foil 33 was stacked on the surface of the resin sheet, the resin sheet and the metal foil 33 were thermally compressed using a thermal compression press, and the resin sheet was heated and cured in an oven, forming the insulating layer 22. Finally, the upper main surface wiring pattern 23 and the lower main surface wiring pattern 24 were patterned by etching the metal foil 33 and the metal plate 31, the multilayer body was once again heated under heating conditions necessary to form the intermetallic compound 26 from the pre-reaction medium, and the manufacture of the circuit board 21 was completed.

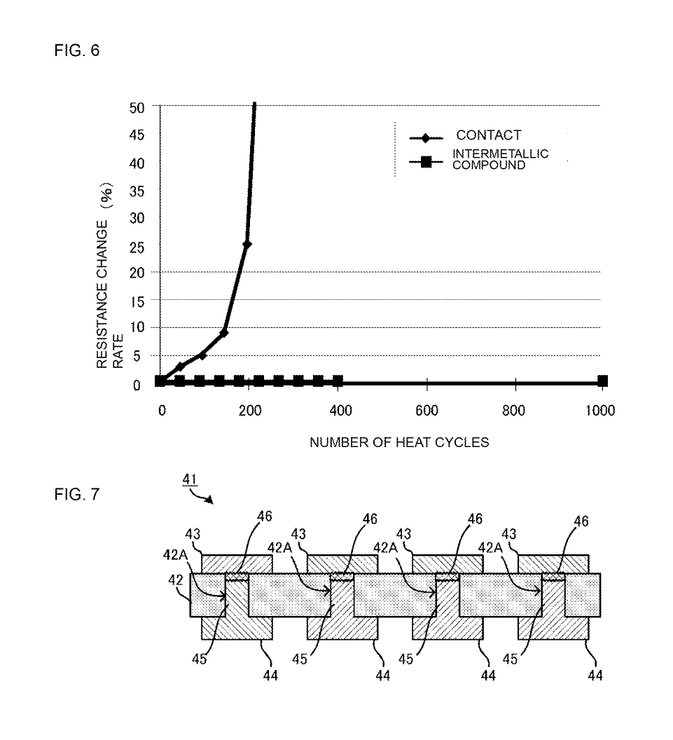

FIG. 6 is a diagram illustrating a relationship between a number of heat cycles and a resistance change rate for the sample of the circuit board 21. Note that the relationship between the number of heat cycles and the resistance change rate is illustrated here for the circuit board according to the embodiment as well as a circuit board according to a comparative example. A circuit board in which an intermetallic compound, a conductive adhesive, or the like is not used to bond the interlayer connection conductors and the upper main surface wiring pattern is used as the circuit board according to the comparative example. Note that the embedded amount of the interlayer connection conductors was 5 μm in both the embodiment and the comparative example.

In the circuit board according to the embodiment, the resistance change rate was stable at zero until approximately 1,000 heat cycles. On the other hand, in the circuit board according to the comparative example, the resistance change rate changes gradually until approximately 100 heat cycles, but the resistance change rate then increases drastically from approximately 200 heat cycles. Based on this, it can be seen that in the circuit board according to the embodiment, the bond between the interlayer connection conductors 25 and the upper main surface wiring pattern 23 is extremely stable. In other words, it was successfully confirmed that an extremely strong connection can be achieved by chemically bonding the interlayer connection conductors 25 to the upper main surface wiring pattern 23 using the intermetallic compound 26 and embedding the intermetallic compound 26 in the upper main surface wiring pattern 23.

Note that in both the embodiment and the comparative example, there are cases where the embedded amount of the interlayer connection conductors will unavoidably become small depending on the pattern shape of the upper main surface wiring pattern. As such, in the case where the embedded amount is low, thermal stress is more likely to act on the connection boundary between the interlayer connection conductors and the upper main surface wiring pattern, which leads to a drop in the reliability of the connection. Even in this case, the reliability of the connection will not drop markedly in the case where the interlayer connection conductors is bonded to the upper main surface wiring pattern using the intermetallic compound, and thus a sufficient reliability can be ensured for the connection even when the upper main surface wiring pattern has a pattern shape in which the embedded amount of the interlayer connection conductors unavoidably becomes small.

### Third Embodiment

Next, a circuit board according to a third embodiment of the present invention will be described.

FIG. 7 is a schematic cross-sectional view of a circuit board 41 according to the third embodiment of the present invention. The circuit board 41 includes an insulating layer 42 comprising an insulating resin, an upper main surface wiring pattern 43 comprising a conductive material, a lower main surface wiring pattern 44 comprising a conductive material, and interlayer connection conductors 45 comprising a conductive material. Although the circuit board 41 has approximately the same configuration as the aforementioned circuit board 1, a surface of an intermetallic compound 46 provided on upper end portions of the interlayer connection conductors 45 is roughened, and as a result, a substantial border surface area between the intermetallic compound 46 and the interlayer connection conductors 45 and a substantial border surface area between the intermetallic compound 46 and the upper main surface wiring pattern 43 are respectively increased to provide an even stronger bond. In other words, the connection is even further reliable.

Although a circuit board according to the present invention has been described in detail thus far, the specific configuration of the circuit board can be designed and altered as desired; the actions and effects described in the aforementioned embodiments are merely examples of the most favorable actions and effects provided by the present invention, and the actions and effects according to the present invention are not intended to be limited to those described in the aforementioned embodiments.
1, 21, 41 . . . circuit board
2, 22, 42 . . . insulating layer
2A . . . through-hole
3, 23, 43 . . . upper main surface wiring pattern
4, 24, 44 . . . lower main surface wiring pattern
5, 25, 45 . . . interlayer connection conductor
6, 26, 46 . . . intermetallic compound
11, 31 . . . metal plate
12, 32 . . . pre-reaction medium
13, 33 . . . metal foil

1. A circuit board comprising:
an insulating layer;
a first wiring pattern and a second wiring pattern disposed on either side of the insulating layer in a thickness direction; and
an interlayer connection conductor passing through the insulating layer in the thickness direction and electrically connecting to the first wiring pattern and the second wiring pattern,
wherein the interlayer connection conductor is:
formed integrally with the first wiring pattern; and
bonded to the second wiring pattern via an intermetallic compound.

2. The circuit board according to claim 1,
wherein the interlayer connection conductor is bonded to the second wiring pattern in a state in which the interlayer connection conductor extends further toward the second wiring pattern beyond a junction boundary between the second wiring pattern and the insulating layer.

3. The circuit board according to claim 1,
wherein a junction boundary between the interlayer connection conductor and the second wiring pattern is roughened.

4. A method for manufacturing the circuit board according to claim 1, the method comprising:
a pre-reaction medium formation process of forming a pre-reaction medium of the intermetallic compound on one surface of a metal plate;
an interlayer connection conductor forming process of partially removing a multilayer body comprising the pre-reaction medium and the metal plate from a side on which the pre-reaction medium is located except that a region for the interlayer connection conductor is not removed;
a layering process of forming the insulating layer and a metal foil, wherein the interlayer connection conductor is embedded in the insulating layer and the metal foil is bonded to a surface of the insulating layer on the multilayer body;
a wiring pattern forming process of forming the first wiring pattern from the metal plate and forming the second wiring pattern from the metal foil; and
a heating process of forming the intermetallic compound by heating the multilayer body to react the pre-reaction medium.

5. The method for manufacturing a circuit board according to claim 4,
wherein the insulating layer formed in the layering process is thinner than a height of the interlayer connection conductor, and the metal foil pressure-bonded to the insulating layer in the layering process is thicker than a height at which the interlayer connection conductor projects from the insulating layer.

6. The circuit board according to claim 2,
wherein a junction boundary between the interlayer connection conductor and the second wiring pattern is roughened.

7. A method for manufacturing the circuit board according to claim 2, the method comprising:
a pre-reaction medium formation process of forming a pre-reaction medium of the intermetallic compound on one surface of a metal plate;
an interlayer connection conductor forming process of partially removing a multilayer body of the pre-reaction medium and the metal plate from a side on which the pre-reaction medium is located except that a region for the interlayer connection conductor is not removed;
a layering process of forming the insulating layer and a metal foil, wherein the interlayer connection conductor is embedded in the insulating layer and the metal foil is bonded to a surface of the insulating layer on the multilayer body;
a wiring pattern forming process of forming the first wiring pattern from the metal plate and forming the second wiring pattern from the metal foil; and
a heating process of forming the intermetallic compound by heating the multilayer body to react the pre-reaction medium.

8. A method for manufacturing the circuit board according to claim 3, the method comprising:
a pre-reaction medium formation process of forming a pre-reaction medium of the intermetallic compound on one surface of a metal plate;
an interlayer connection conductor forming process of partially removing a multilayer body of the pre-reaction medium and the metal plate from a side on which the pre-reaction medium is located except that a region for the interlayer connection conductor is not removed;
a layering process of forming the insulating layer and a metal foil, wherein the interlayer connection conductor is embedded in the insulating layer and the metal foil is bonded to a surface of the insulating layer on the multilayer body;
a wiring pattern forming process of forming the first wiring pattern from the metal plate and forming the second wiring pattern from the metal foil; and
a heating process of forming the intermetallic compound by heating the multilayer body to react the pre-reaction medium.
